(19) United States
(12) Patent Application Publication
(10) Pub. No.: US 2019/0005169 A1
(43) Pub. Date: Jan. 3, 2019

(54) Dynamic Design of Complex System-of-Systems for Planning and Adaptation to Unplanned Scenarios

(71) Applicant: Siemens Aktiengesellschaft, Munich (DE)

(72) Inventors: Lucia Mirabella, Plainsboro, NJ (US); Sanjeev Srivastava, Princeton Junction, NJ (US); Arquimedes Martinez Canedo, Plainsboro, NJ (US)

(21) Appl. No.: 16/060,167

(22) PCT Filed: Dec. 14, 2016
(86) PCT No.: PCT/US2016/066580

§ 371 Date: Jun. 7, 2018

Related U.S. Application Data
(60) Provisional application No. 62/266,929, filed on Dec. 14, 2015.

(51) Int. Cl. G06F 17/50; G06Q 50/00; G06Q 10/06; G06Q 50/26

(52) U.S. Cl. CPC G06F 17/5009; G06Q 50/265; G06Q 10/067; G06Q 50/01

(57) ABSTRACT

A computer-implemented method for designing a system-of-systems for adaptation to unplanned scenarios includes receiving a plurality of sensor outputs and consolidating the plurality of sensor outputs into a current system status report. Next, in response to detection of a new unplanned need, currently available system resources are identified. An abstract description of a system-of-systems is updated based on the currently available system resources. Using the abstract description of the system-of-systems, feasible solutions are determined that could satisfy the new unplanned need. Each feasible solution comprises instructions for using resources included in the system-of-systems. A simulation network comprising a plurality of simulation models is generated based on the abstract description of the system-of-systems. Then, the simulation network is used to select one of the plurality of feasible solutions.

### CROSS-REFERENCE TO RELATED APPLICATIONS

This application claims the benefit of U.S. Provisional Application Ser. No. 62/266,929 filed Dec. 14, 2015, which is incorporated herein by reference in its entirety.

### TECHNICAL FIELD

The present disclosure generally relates to systems, methods, and apparatuses for designing a complex system-of-systems for planning and adaptation to unplanned scenarios. The techniques described herein may be applied for example, the modeling of any complex system.

### BACKGROUND

Currently, dynamic complex system-of-systems like urban infrastructures are difficult to model and impossible to systematically design; thus leading to: inferior performance; unexpected problems; and weak resilience, especially to other unplanned scenarios. Typically, conventional planning tools are used to simulate a large number of pre-planned scenarios and to identify how modifications to the system would perform under each of them. This approach results in system designs that are likely to perform well under certain emergency scenarios, but cannot provide information on how to adapt the system to scenarios that have not been explicitly planned a priori.

For example, a blizzard can cause major disruption in a region's transportation networks, closing down subways and trains, slowing car traffic, and cancelling flights; also affecting other systems such as the power grid. Currently, city planners use prior experiences to prepare for a blizzard by pre-locating assets such as snow plows and salt to clear the roads. National Guard and State Troopers are dispatched in patrols for rescue missions and to prevent crime. Shelters are established and evacuation recommendations are communicated to the community. During and after the blizzard, city planners use various ad-hoc information feedback loops to manage the assets. Unfortunately, city planners must improvise before, during, and after a natural disaster without design tools.

Recently, cities in the United States are making urban infrastructure data accessible to developers and providing development frameworks for the community to create useful applications (e.g., tracking snow plows in real-time). While these initiatives and similar services are a step forward, the available data sets are based on historical data and can only reflect known events. Therefore, existing tools are restricted to designing alternative urban configurations against playbook scenarios. These tools are limited to system resilience, defined as the use of existing capabilities—the interplay between function, behavior, and structure—against predetermined scenarios to provide functional continuity and risk management; these are primarily used for planning in pre-event and disaster stages.

Accordingly, it is desired to create a framework for analyzing complex system-of-systems that offers the capability of adaptive resilience, thereby providing a more robust, consistent, and reliable understanding of how to optimally use system resources.

### SUMMARY

Embodiments of the present invention address and overcome one or more of the above shortcomings and drawbacks, by providing methods, systems, and apparatuses related to a complex system-of-systems for planning and adaptation to unplanned scenarios. These techniques and technologies are capable of fully considering the various interdependencies of heterogeneous systems, over space and time, and the consequent emergent behaviors.

According to some embodiments, a computer-implemented method for designing a system-of-systems for adaptation to unplanned scenarios includes receiving sensor outputs and consolidating the sensor outputs into a current system status report. Next, in response to detection of a new unplanned need, currently available system resources are identified. An abstract description of a system-of-systems is updated based on the currently available system resources. The abstract description may also be updated based one or more of current system behaviors, current system lower-level functions, and current system constraints. Additionally, the abstract description may be updated for future conditions by interpolating based on the currently available system resources to determine predicted system resources that will be available at a future time, Using the abstract description of the system-of-systems, feasible solutions are determined that could satisfy the new unplanned need. Each feasible solution comprises instructions for using resources included in the system-of-systems. A simulation network comprising simulation models is generated based on the abstract description of the system-of-systems. Then, the simulation network is used to select one of the feasible solutions. In some embodiments, based on the selected feasible system configuration, presenting a GUI is presented which includes (i) a listing of selected system resources; (ii) a listing of selected system behaviors; and (iii) an indication of one or more relationships between the selected system resources and the selected system behaviors.

In some embodiments of the aforementioned system, the new unplanned need is automatically identified based on the sensor outputs. For example, in one embodiment, a system status is determined based on the sensor outputs. This system status is compared to one or more reference system statuses to identify critical needs and the new unplanned need is selected from the critical needs. In one embodiment, the critical needs are sorted by priority and the highest ranking critical need is selected as the new unplanned need.

Various types of sensor outputs may be used with the aforementioned method for example, in some embodiments, the sensor outputs comprise sensor outputs from one or more physical sensors. Additionally (or alternatively), the sensor outputs may include sensor outputs from one or more non-physical sensors. For example, in one embodiment, one of the non-physical sensors is a social network and the sensor outputs comprise a listing of communications on the social network. In some embodiments, the sensor outputs are consolidated into the current system status report using a computing process that implements one or more sheaf theory-based techniques.

According to other embodiments, a second method for designing a system-of-systems for adapting to unplanned scenarios comprises generating input configurations corresponding to a system-of-systems and performing a planning workflow for each input configuration. The planning workflow includes generating a potential need related to the system-of-systems, and identifying feasible solutions that could satisfy the potential need. Each feasible solution comprises instructions for using resources included in the system-of-systems. The work flow further includes generating a simulation network comprising simulation models based on an abstract description of the system-of-systems and using the simulation network to determine a number of the feasible solutions satisfying a user-selected objective. For example, in one embodiment, the feasible solutions that could satisfy the potential need are identified based on currently available resources associated with the system-of-systems. The input configuration having a greatest number of the feasible solutions in comparison to other input configurations may then be designated as the most resilient input configuration. In one embodiment, based on the most resilient input configuration, a GUI (e.g., an Internet web browser on a user device) is presented which includes (i) a listing of selected system resources; (ii) a listing of selected system behaviors; and (iii) an indication of one or more relationships between the selected system resources and the selected system behaviors. In one embodiment, a parallel computing environment is used to execute the simulation models in parallel to determine the number of the feasible solutions satisfying the user-selected objective.

In some embodiments of the aforementioned second method, the potential need related to the system-of-systems is generated by randomly modifying one or more values in the abstract description of the system-of-systems. Alternatively, the potential need is generated based probabilities of failure or unavailability of system resources and links between the system resources.

In other embodiments of the present invention, a system for designing a system-of-systems for adaptation to unplanned scenarios includes a sensor interface, one or more processors, and a presentation interface. The sensor interface is configured to receive sensor outputs related to a system-of-systems. The one or more processors consolidate the sensor outputs into a current system status report and in response to detection of a new unplanned need, identify currently available system resources. The processors update an abstract description of the system-of-systems based on the currently available system resources, and use the abstract description of the system-of-systems to determine feasible solutions that could satisfy the new unplanned need. Each feasible solution comprises instructions for using resources included in the system-of-systems. Then, the processors generate a simulation network comprising simulation models based on the abstract description of the system-of-systems, and use the simulation network to select one of the feasible solutions. In one embodiment, the one or more processors are included in a parallel processing platform configured to execute the simulation models in parallel to select the selected feasible solution. The presentation interface included in the system is configured to use the selected feasible system configuration to presenting a graphical user interface comprising: (i) a listing of selected system resources; (ii) a listing of selected system behaviors; and (iii) an indication of one or more relationships between the selected system resources and the selected system behaviors.

Additional features and advantages of the invention will be made apparent from the following detailed description of illustrative embodiments that proceeds with reference to the accompanying drawings.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 provide a high-level overview of a SoS to which the techniques described herein may be applied;

FIG. 2 shows the software architecture for designing a complex system-of-systems for planning and adaptation to unplanned scenarios, according to some embodiments of the present invention;

FIG. 3 provides example of a graphical user interface, as it may be configured and arranged in some embodiments;

FIG. 4 illustrates an example of a simulation network, as it may be implemented in some embodiments;

FIG. 5 provides an example of offline tool configuration method that may be implemented by the software architecture, according to some embodiments;

FIG. 6 presents an example of three use cases focusing on resilience, adaptation, living systems related issues, respectively, that may be used in accordance with some embodiments;

FIG. 7 illustrates an online adaption workflow that may be used in some embodiments of the present invention;

FIG. 8 provides an example of a parallel processing memory architecture that may be utilized to perform computations related to execution of the various workflows and architectures discussed herein, according to some embodiments of the present invention.

### DETAILED DESCRIPTION

The following disclosure describes the present invention according to several embodiments directed at methods, systems, and apparatuses related to designing a complex system-of-systems for planning and adaptation to unplanned scenarios. Briefly, the techniques described herein utilize a dashboard that can be used to both plan a system-of-systems (SoS), for improved resiliency with respect to SoS designed with standard tools, (“planning mode”) and to adapt an existing SoS to unplanned needs and configurations (“adaptation mode”). Such dashboard will take as input information on the known resources and behaviors in the considered SoS, on the known functions the SoS can perform in normal conditions and on the constraints that exist. In planning mode, this information will reflect the design space, which the user is willing to explore. In adaptation mode, this information will reflect the characteristics of the existing system, under normal operations (i.e. not under the emergency scenario). The techniques described herein are generally applicable to any complex system including, for example, urban infrastructure, manufacturing plants, product life cycles, and robotics.

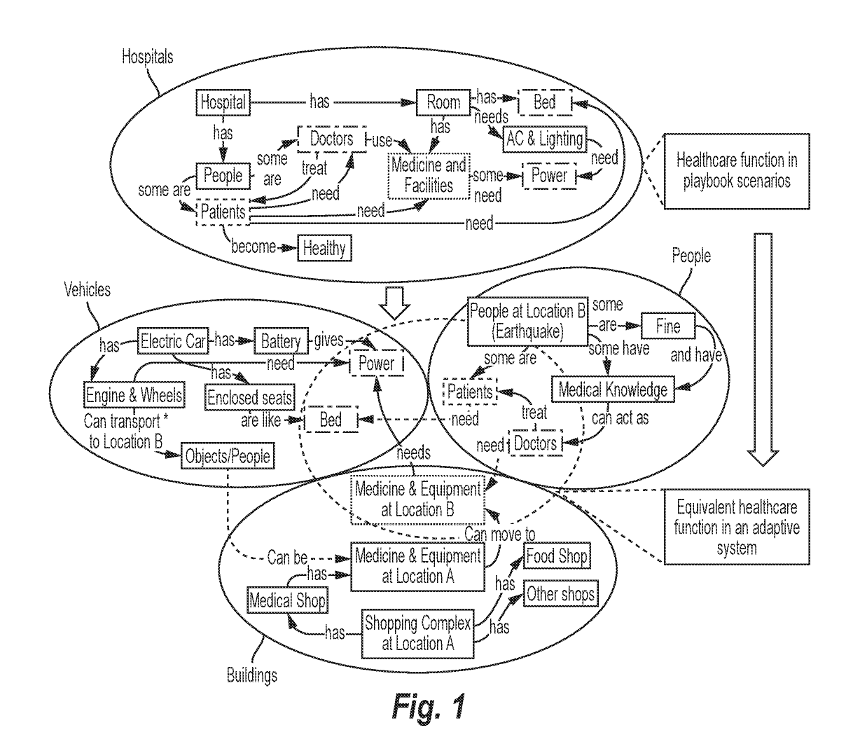

FIG. 1 provides a high-level overview of a SoS to which the techniques described herein may be applied. The term SoS refers to a complex system which combines the resources, capabilities, and overall function of a plurality of task-oriented or dedicated systems. The example presented in FIG. 1 corresponds to a SoS for healthcare-related functions. Using the tools discussed herein, the SoS presented in FIG. 1 may be analyzed to identify specific configurations of the constituent systems that are able to be readily adapted to unplanned needs that may exist under normal operation conditions and emergency scenarios.

In FIG. 1, there are three constituent systems: vehicles, people, and buildings. Each system is defined by a set of resources and relationships between those resources. Thus, for example, in the vehicle system, an electric car resource comprises battery, enclosed seats, engine, and wheel resources. In some embodiments, each constituent system may have one or more sensors that provide information on the current state of its resources. By combining the three constituent systems, a SoS can be created as shown by the dotted line in FIG. 1. In this example, the three constituent systems are combined in a manner that provides healthcare functions that would ordinarily be provided by a hospital system (shown in the top portion of FIG. 1). For example, the hospital subsystem includes power and bed resources. These can be provided to the SoS using the power provided by the electric car's battery and the enclosed seats, respectively.

To identify a configuration(s) of the SoS suitable to meet the needs of a particular scenario (e.g., providing hospital services in the event of an earthquake as shown in FIG. 1), the the techniques described herein compose a simulation network comprising a plurality of simulation models. Using the network, a combined simulation may be performed to identify and evaluate potential solutions to the needs. In some embodiments, a graphical user interface (GUI) is used to present the results of this analysis and facilitate further interactions with the user.

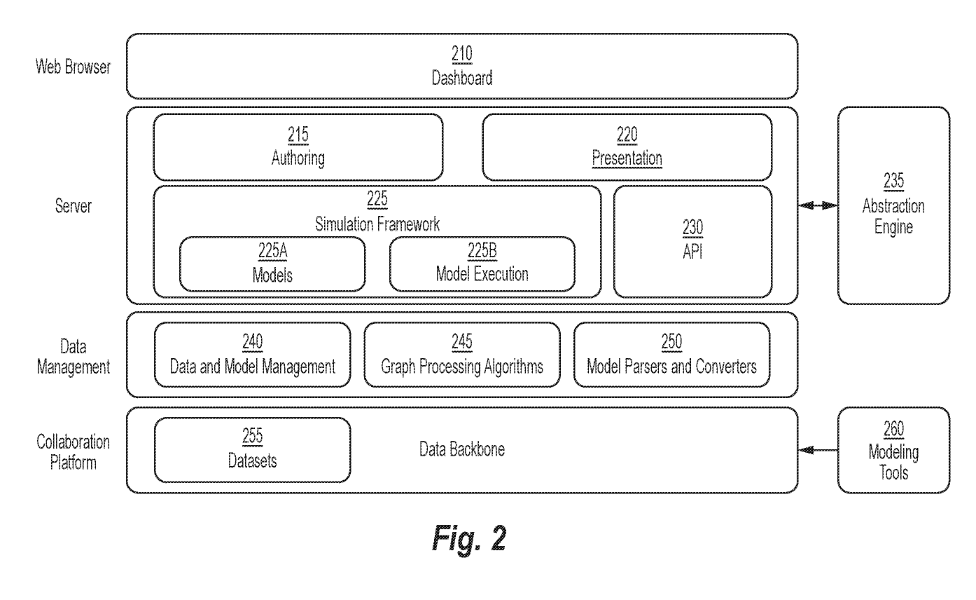

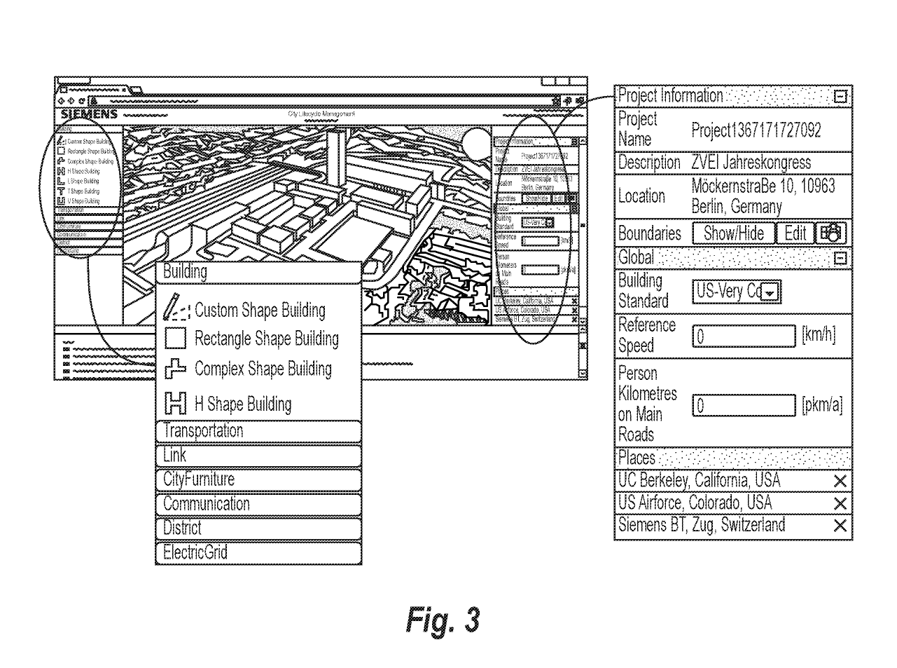

FIG. 2 shows the software architecture 200 for designing a complex system-of-systems for planning and adaptation to unplanned scenarios, according to some embodiments of the present invention. The Dashboard 210 is a web application that will be executed in the user's web browser with advanced visualization capabilities. One example of the Dashboard 210, as it may be configured and arranged in some embodiments, is shown in FIG. 3. Users may import, for example, an existing city, edit a city, select and create scenarios, select metrics, perform simulations, manage and visualize data, results, and configurations. The Server layer comprises an Authoring Module 215 for receiving these user inputs via the Dashboard 210. Similarly a Presentation Module 220 configures the presentation of output data within the Dashboard 210. Both of these Modules 215, 220 may be implemented, for example, using a specific software library, class, or other collection of suitable software functions.

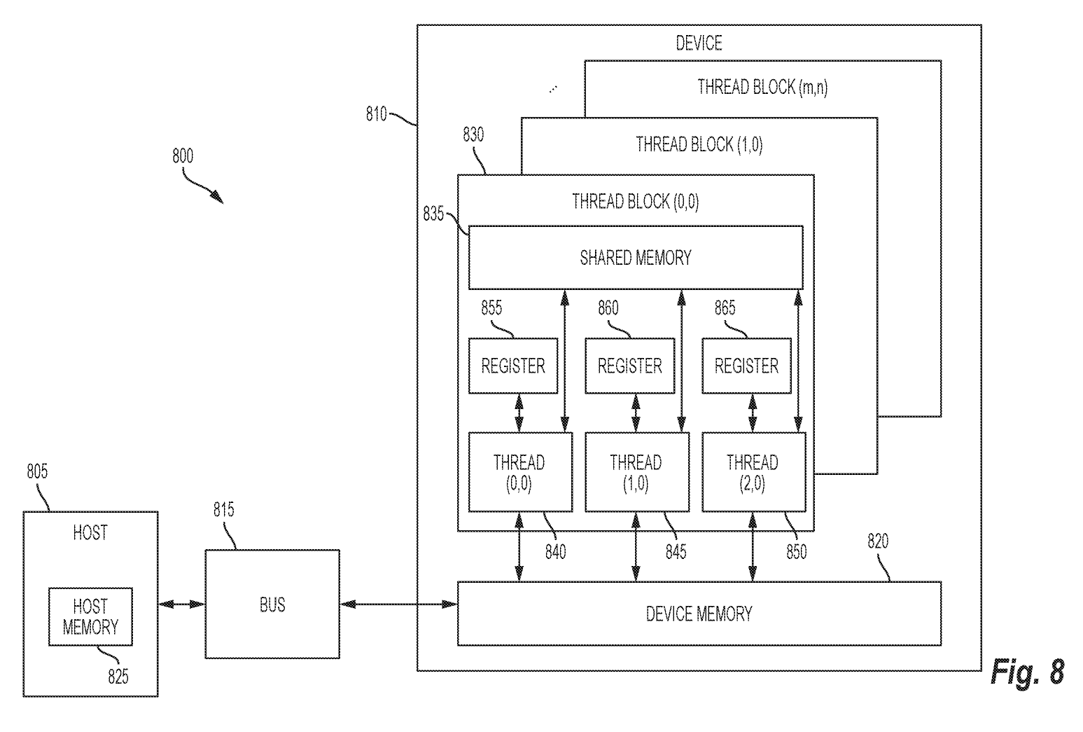

Continuing with reference to FIG. 2, a Simulation Framework 225 contains Models 225A, and a Model Execution Module 225B. Models 225A comprise a plurality of simulation models stored in a database or other storage mechanism. The Model Execution Module 225B manages the execution of the models, either on the server's computing resources or using an external computing platform. For example, as described in further detail below with respect to FIG. 8, in some embodiments, a parallel processing environment is used to execute each simulation network.

The Application Program Interface (API) 230 in the software architecture 200 is the programmatic interface to external devices. The Server interacts with the Abstraction Engine 235. The abstraction engine may be designed in a variety of ways, depending on the overall configuration of the dashboard system. For example, in one embodiment, the abstraction engine parses the functional, behavioral, and structural models' properties (e.g., height, mass, rigid bodies, differential equations), and maps the minimal set of properties to named functions (at the multiple levels of functional decomposition). These named functions will contain just the right level of abstraction to reason about the SoS and calculate a resilient configuration. This process is similar to giving a set of heterogeneous models to a group of domain-experts and them finding the minimal functional representation of the system that is compatible with other systems in its environment. Using the abstract SoS representation, the proposed framework calculates the candidate SoS reconfigurations to achieve the desired services. The Abstraction Engine is expected to receive a functional model as an input, and return a set of configurations of the SoS with references to the functional models. The objective is finding configurations of predictive models (at different levels of fidelity) that achieve composition and compositionality that can be used to predict the function, behavior, and structure of the system under the given constraints and events. This is equivalent of giving a problem to a group of domain-experts, and them creating and assembling various configurations of predictive models that can be simulated as a whole. The results are ranked using the baseline performance as a reference, and a strategy (computed by the Abstraction Engine) and SoS reconfiguration is selected to achieve the defined goals.

The Data Management layer contains the Data and Model Management Module 240 that combines simulation models according to predetermined rules to create simulation networks. The generation of the simulation network is driven by the set of metrics that needs to be computed and the relationships pre-defined between system components. As an example, if the time to perform a set of actions is the metric of interest, the system will look for a model for performance time in each of the components that represent the considered actions, and run these models in a sequence, provided that the actions are performed sequentially, feeding the result of the first model of action to the subsequent one. This Module 240 utilizes Graph Processing Algorithms 245 and Model Parsers and Converters 250 to facilitate generation and processing of the simulation networks. These modules identify the connections between system components in the graph that represents it, identifies the input/output variables of the models associated to them, and identify the proper conversions needed to allow interaction among the models.

The Collaboration Platform layer is the Data Backbone that contains the Datasets 255 generated using the Simulation Framework 225. External Modeling Tools 260 may be used to create and edit models in their native formats, which may then be uploaded to Simulation Framework 225 via the Data Backbone. In this way, the Simulation Framework 225 may be updated continuously with new, more up-to-date models thereby providing a more robust simulation environment.

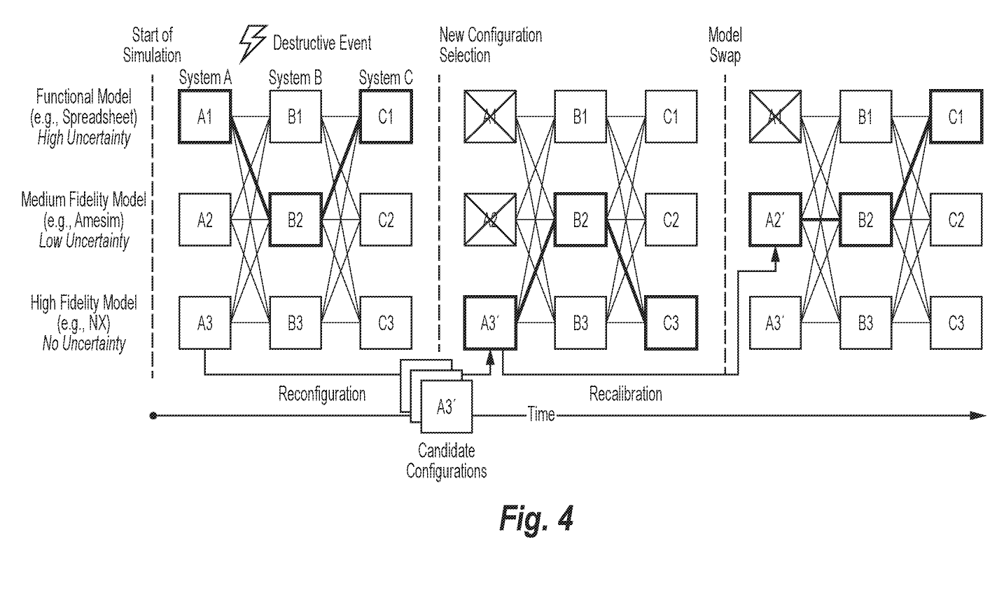

FIG. 4 illustrates an example of a simulation network, as it may be implemented in some embodiments. This example comprises three systems: vehicles (System A), roads (System B), and hospitals (System C). All models representing the systems in various fidelity levels (A1, A2, A3, B1, B2, B3, C1, C2, C3) are available in the Simulation Framework 225. Before launching the simulation, a request is sent to the Abstraction Engine 235 to obtain the composition of models necessary to evaluate the system's function (e.g., “Transport people to hospitals”). The Abstraction Engine 235 engine returns the set {A1, B2, C1} for the software architecture 200 to compose the simulation network that will be used until an event is detected. Events that cause permanent structure and behavior damage trigger a Reconfiguration request to Abstraction Engine 235 to find alternative system configurations through functional equivalence; and non-destructive events can reuse the existing simulation as they only affect constraints.

Continuing with reference to FIG. 4, one concrete reconfiguration example is the use of 3D geometric models of a car and a paddle boat to synthesize a makeshift “speedboat” represented by A3′. When a new configuration is selected, after evaluating the candidate configurations, the server in the software architecture 200 pushes a new request to Abstraction Engine 235 to obtain a new composition of models necessary to assess the system's function. This is necessary because the original medium fidelity and functional models A1 and A2 are no longer valid because they do not accurately represent the function, behavior, structures, constraints and events of the new “speedboat” A3′. In this example, the new set is {A3′, B2, C3} and it can be used until a new event is detected, or until simulation recalibration is completed. Recalibration is important because simpler and less computationally expensive models can be reused after the key performance characteristics are obtained from the high fidelity models. When recalibration succeeds, the software architecture 200 may perform a model swap, e.g., from A3′ to A2′. Model swaps push a request to the Abstraction Engine 235 to obtain a new set (e.g., {A2′, B2, C1}). In some embodiments, the simulation network will be continuously evaluating the state of the system, reconfiguring, recalibrating, and swapping models, multiple systems at a time.

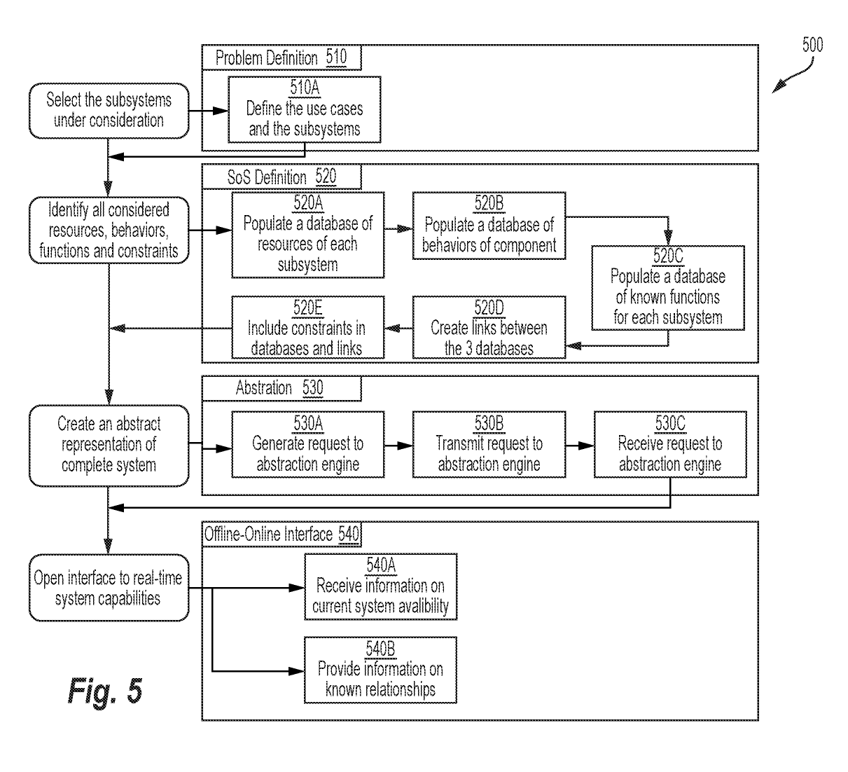

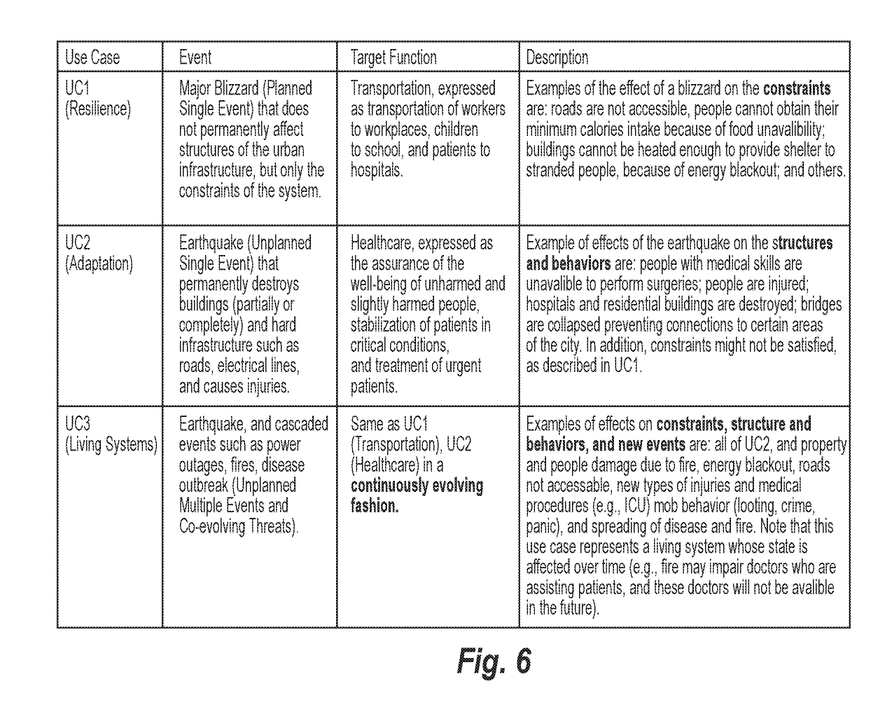

FIG. 5 provides an example of offline tool configuration method 500 that may be implemented by the software architecture 200, according to some embodiments. The method 500 begins at step 505 where the subsystems under consideration are identified, for example, based on user input. Based on the identified subsystems, the Problem Definition Phase 510 is started during which, at step 510A, the relevant use cases and the details of the subsystem are defined. FIG. 6 presents an example of three use cases focusing on resilience, adaptation, living systems related issues, respectively.

During the Problem Definition Phase, the considered resources, behaviors, functions and constraints of the subsystems under consideration are identified during a “SoS Definition” Phase 520. Three databases are created during this Phase 520, including a database of resources for each subsystem, a database of behaviors for each component, and a database of known functions for each subsystem. Such databases can be populated manually by a subject matter expert, or by browsing existing domain-specific databases, or potentially by automatically analyze literature on the specific problem, using natural language processing techniques. Next at step 520D, links are created between the three databases populated at steps 520A-520C. An example for such creation is the following: if function A can be performed by object B while it exhibits behavior C consuming resource D, links will be created between A to B, C to B and D. Then, at step 520E, constraints are applied to the databases populated at steps 520A-520C and the links created at step 520D. Constraints can be represented associated to behaviors. For example, a car can move from location x to location y only if it has enough fuel. Hence, the behavior of moving a car from x to y will happen only after the constraint on fuel has been met. Constraints can be created similarly to how the databases in Phase 520 are created.

Continuing with reference to FIG. 5, an abstract representation of the complete system is generated with an abstraction engine during the Abstraction Phase 530. At step 530A-530B, a request is generated to an abstraction engine. As discussed above, the abstraction engine is a connected software tool that provides a mathematical representation for the system using various models (e.g., low-fidelity, medium-fidelity, high-fidelity, mechanical, electrical, etc.). This abstraction engine may be internal to the system hosting the dashboard or, in some instances, an external abstraction engine may be used (e.g., hosted by another party). At step 530C, this mathematical representation is received from the abstraction engine in response to the original request.

The result of the abstract SoS representation may be queried in the Offline-Online Interface Phase 540 to identify a set of lower level functions, able to satisfy the need identified by the system. Additionally, this result may be used to identify resources and links (among the available ones) to perform a given function. Additional input is provided at run-time during the Offline-Online Interface Phase 540, when the tool is utilized to adapt the SoS to an unplanned scenario. In this case, a set of sensors (of various types), embedded in the SoS, provides data to the tool with the purpose of both identifying any unpredicted need and to assess the current status of the SoS. Thus, at step 540B, information on the current system availability is received and, at step 540B, information is provided on known system relationships.

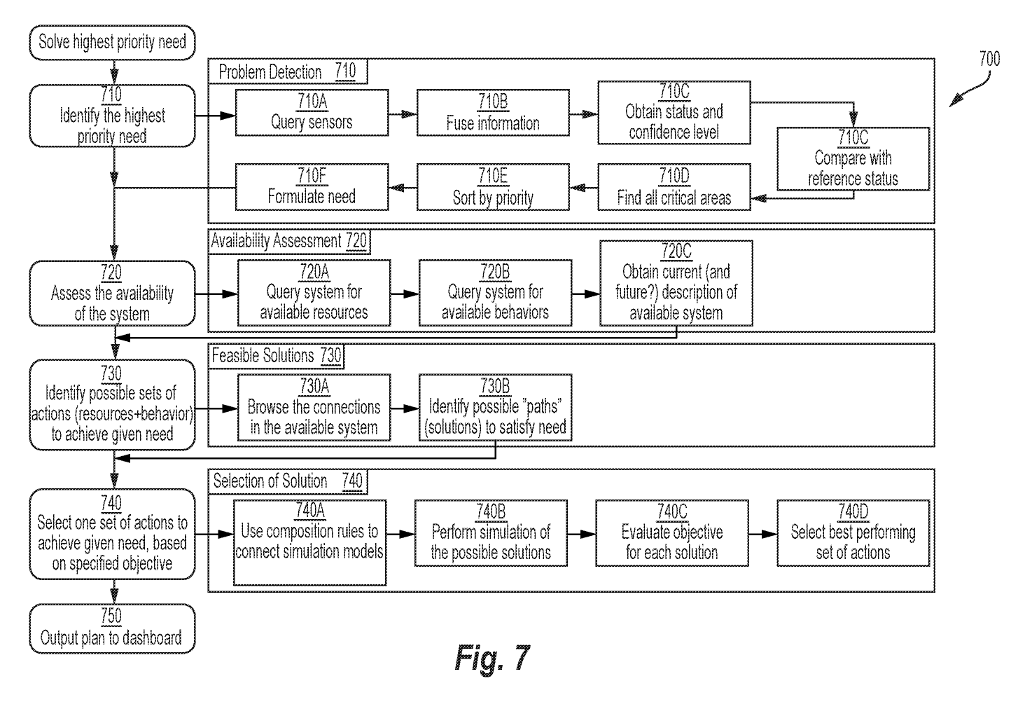

FIG. 7 illustrates an online adaption workflow 700 that may be used in some embodiments of the present invention. In adaptation mode, the Dashboard computes and outputs to the user the set of resources and “instructions” to use in space and time to react to a detected scenario and satisfy the need(s) that is (are) identified as priority. The workflow 700 in this case includes the following phases: a Problem Detection Phase 710, an Availability Assessment Phase 720, a Feasible Solutions Phase 730, and a Selection of Solution Phase 740.

The Problem Detection Phase 710 is performed periodically during the operation, when new sensors information is detected, to identify the highest priority, unplanned needs of the SoS. Starting at step 710A, the various sensors are queried to gather relevant information. These sensors may include traditional physical sensors (e.g. thermal sensors, visual sensors, etc.), as well as “soft” sensors such as communications on social networks. Next, at step 710B, the information from the sensors is fused. This problem can be tackled, for example, using Sheaf Theory or similar technique, and will result in information on the current status of the system, equipped with the accuracy of such information, based on the accuracy of the utilized sensors and on the discrepancy among the incoming pieces of information. At step 710C, the detected status of the system is compared with a reference (set of) status(es). These reference statuses may be specified, for example based on user and/or based on a historical analysis of the system under normal working conditions. At step 710D, statuses that deviate from the reference values by more than some threshold amount are characterized as “critical.” Next, at step 710E, the statuses that were identified as critical are sorted by priority. The priority list can be determined “a priori” based on general rules or knowledge (e.g. it is of higher priority to resolve safety issues than to resolve networking issues) or based on user input. Finally, at step 710F, the system identifies a high-level function/need/mission to accomplish with the reconfiguration, basing the decision of the main mission on the priority list (e.g. mission of providing healthcare if survival of humans is the priority).

During the Availability Assessment 720, once a new need is detected, the sensing system will be queried to identify the resources, behaviors, lower-level functions and constraints that are available or active at the present time. This assessment is performed at steps 720A and 720B. This information will be used to update the abstract description of the SoS (“Offline-Online Interface”) at step 720C, before proceeding to the next phase. In addition, in some embodiments, additional information may be gathered on the predicted availability in the near future, or its uncertainty, can be added to this phase, for more robust adaptation.

The objective of the Feasible Solutions Phase 730 is to identify, in the currently available system, solutions (in terms of usage of resources and “instructions”) that could satisfy the identified needs. Thus, at step 730A, the connections in the available system are browsed. These connections can reside in any of the sub-systems within the SoS. Then, at step 730B, the possible “paths” (i.e., solutions) to satisfy the need are identified. This identification can be done using graph analysis techniques.

Once a set of feasible solutions is identified, the choice among them can be driven by the use of simulation models during the Selection of Solution Phase 740. However, given the dynamic nature of the SoS structure, existing tools will be composed on the fly based on the abstract description of the current SoS. Starting at step 740A, composition rules are used to connect simulation models into a simulation network. The composition rules will be based on the functions and behaviors of various structures within the simulation models, inputs and outputs of models, and the levels of models fidelity. The simulation network will have the ability to propagate the uncertainty detected in the input (e.g. on the availability of resources) to the predicted outcome. Depending on the simulation models selected in the network, different objective functions (e.g. cost, time of implementation, probability of success, etc.) could be evaluated to drive the choice on the “best” among the considered solutions. Next, at step 740B, the connected simulation models are used to perform a simulation of all possible solutions and, at step 740C, the objective for each solution is evaluated. Based on this evaluation, the best performing set of actions is selected at step 740D.

As outcome of this process, at 750, the dashboard may output a set of resources, behaviors and links among them that can be employed to satisfy the automatically identified unplanned need.

In some embodiments of the planning mode, the dashboard will output the resources and functionalities that the SoS needs to include to achieve a high level of resilience (according to a metric defined below). This will be achieved by utilizing a modified version of the workflow described above with respect to FIG. 7 for the adaptation mode. First, the Problem Detection Phase 710 and Availability Assessment Phase 720 are substituted by a Problem Generation Phase, where perturbation on the abstract SoS are generated either randomly or using prior information on the probability of failure/unavailability of resources (and their behaviors) and links between them. The Selection of Solution Phase 740 is modified by substituting the task “Select best performing set of actions” (i.e., step 740D) with “Count the number of solutions that satisfy a minimum threshold on the selected objective”. This number will be considered as proxy for a resiliency metric. This modified workflow may be repeated for several possible input configurations of the SoS (set in the offline tool configuration) and these input configurations will be ranked based on the number of acceptable solutions under the considered simulated problems. The input configuration with the highest count of acceptable solutions will be selected as the most resilient.

FIG. 8 provides an example of a parallel processing memory architecture 800 that may be utilized to perform computations related to execution of the various workflows and architectures discussed herein, according to some embodiments of the present invention. This architecture 800 may be used in embodiments of the present invention where NVIDIA™ CUDA (or a similar parallel computing platform) is used. The architecture includes a host computing unit (“host”) 805 and a graphics processing unit (GPU) device (“device”) 810 connected via a bus 815 (e.g., a PCIe bus). The host 805 includes the central processing unit, or “CPU” (not shown in FIG. 8), and host memory 825 accessible to the CPU. The device 810 includes the graphics processing unit (GPU) and its associated memory 820, referred to herein as device memory. The device memory 820 may include various types of memory, each optimized for different memory usages. For example, in some embodiments, the device memory includes global memory, constant memory, and texture memory.

Parallel portions of a deep learning application may be executed on the architecture 800 as “device kernels” or simply “kernels.” A kernel comprises parameterized code configured to perform a particular function. The parallel computing platform is configured to execute these kernels in an optimal manner across the architecture 800 based on parameters, settings, and other selections provided by the user. Additionally, in some embodiments, the parallel computing platform may include additional functionality to allow for automatic processing of kernels in an optimal manner with minimal input provided by the user.

The processing required for each kernel is performed by grid of thread blocks (described in greater detail below). Using concurrent kernel execution, streams, and synchronization with lightweight events, the architecture 800 of FIG. 8 (or similar architectures) may be used to parallelize training of a deep neural network. For example, in some embodiments, the operations of the simulation platform may be partitioned such that multiple kernels execute simulate different configurations simultaneously (e.g., different viewpoints, lighting, textures, materials, effects, etc.). In other embodiments, the simulation network itself may be implemented such that various operations performed with the creation, training, and use of the network are done in parallel.

The device 810 includes one or more thread blocks 830 which represent the computation unit of the device 810. The term thread block refers to a group of threads that can cooperate via shared memory and synchronize their execution to coordinate memory accesses. For example, in FIG. 8, threads 840, 845 and 850 operate in thread block 830 and access shared memory 835. Depending on the parallel computing platform used, thread blocks may be organized in a grid structure. A computation or series of computations may then be mapped onto this grid. For example, in embodiments utilizing CUDA, computations may be mapped on one-, two-, or three-dimensional grids. Each grid contains multiple thread blocks, and each thread block contains multiple threads. For example, in FIG. 8, the thread blocks 830 are organized in a two dimensional grid structure with m+1 rows and n+1 columns. Generally, threads in different thread blocks of the same grid cannot communicate or synchronize with each other. However, thread blocks in the same grid can run on the same multiprocessor within the GPU at the same time. The number of threads in each thread block may be limited by hardware or software constraints. To address this limitation, workflow operations may be configured in various manners to optimize use of the parallel computing platform. For example, in some embodiments, various components of the simulation network may be performed in parallel. In one embodiment, multiple simulation models included in the network are executed in parallel. In other embodiments, the simulation network can evaluate multiple configurations in parallel, thus reducing the overall time for planning and/or adaptation.

Continuing with reference to FIG. 8, registers 855, 860, and 865 represent the fast memory available to thread block 830. Each register is only accessible by a single thread. Thus, for example, register 855 may only be accessed by thread 840. Conversely, shared memory is allocated per thread block, so all threads in the block have access to the same shared memory. Thus, shared memory 835 is designed to be accessed, in parallel, by each thread 840, 845, and 850 in thread block 830. Threads can access data in shared memory 835 loaded from device memory 820 by other threads within the same thread block (e.g., thread block 830). The device memory 820 is accessed by all blocks of the grid and may be implemented using, for example, Dynamic Random-Access Memory (DRAM).

Each thread can have one or more levels of memory access. For example, in the architecture 800 of FIG. 8, each thread may have three levels of memory access. First, each thread 840, 845, 850, can read and write to its corresponding registers 855, 860, and 865. Registers provide the fastest memory access to threads because there are no synchronization issues and the register is generally located close to a multiprocessor executing the thread. Second, each thread 840, 845, 850 in thread block 830, may read and write data to the shared memory 835 corresponding to that block 830. Generally, the time required for a thread to access shared memory exceeds that of register access due to the need to synchronize access among all the threads in the thread block. However, like the registers in the thread block, the shared memory is typically located close to the multiprocessor executing the threads. The third level of memory access allows all threads on the device 810 to read and/or write to the device memory. Device memory requires the longest time to access because access must be synchronized across the thread blocks operating on the device. Thus, in some embodiments, the processing of each simulation network is coded such that it primarily utilizes registers and shared memory and only utilizes device memory as necessary to move data in and out of a thread block.

The embodiments of the present disclosure may be implemented with any combination of hardware and software. For example, aside from parallel processing architecture presented in FIG. 8, standard computing platforms (e.g., servers, desktop computer, etc.) may be specially configured to perform the techniques discussed herein. In addition, the embodiments of the present disclosure may be included in an article of manufacture (e.g., one or more computer program products) having, for example, computer-readable, non-transitory media. The media may have embodied therein computer readable program code for providing and facilitating the mechanisms of the embodiments of the present disclosure. The article of manufacture can be included as part of a computer system or sold separately.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

An executable application, as used herein, comprises code or machine readable instructions for conditioning the processor to implement predetermined functions, such as those of an operating system, a context data acquisition system or other information processing system, for example, in response to user command or input. An executable procedure is a segment of code or machine readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface (GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity (including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers and processes can be implemented using hardware components, software components, and/or combinations thereof. No claim element herein is to be construed under the provisions of 35 U.S.C. 112, sixth paragraph, unless the element is expressly recited using the phrase “means for.”

1. A computer-implemented method for designing a system-of-systems for adaptation to unplanned scenarios, the method comprising:
receiving a plurality of sensor outputs;
consolidating the plurality of sensor outputs into a current system status report;
in response to detection of a new unplanned need, identifying currently available system resources;
updating an abstract description of a system-of-systems based on the currently available system resources;
using the abstract description of the system-of-systems to determine a plurality of feasible solutions that could satisfy the new unplanned need, wherein each feasible solution comprises instructions for using resources included in the system-of-systems;
generating a simulation network comprising a plurality of simulation models based on the abstract description of the system-of-systems;
reconfiguring, in an abstraction engine, the simulation network by replacing the simulation network with an alternative simulation network when an event causing permanent structure or behavior damage is detected during simulation; and
using the alternative simulation network to select one of the plurality of feasible solutions.

2. The method of claim 1, further comprising:
based on the selected feasible system configuration, presenting a graphical user interface comprising: (i) a listing of selected system resources; (ii) a listing of selected system behaviors; and (iii) an indication of one or more relationships between the selected system resources and the selected system behaviors.

3. The method of claim 1, wherein the new unplanned need is automatically identified based on the plurality of sensor outputs.

4. The method of claim 3, further comprising:
determining a system status based on the plurality of sensor outputs;
comparing the system status to one or more reference system statuses to identify a plurality of critical needs;
selecting the new unplanned need from the plurality of critical needs.

5. The method of claim 4, further comprising:
sorting the plurality of critical needs by priority; and
selecting a highest ranking critical need from the sorted plurality of critical needs as the new unplanned need.

6. The method of claim 1, wherein the plurality of sensor outputs are consolidated into the current system status report using a sheaf theory-based computing process.

7. The method of claim 1, wherein the plurality of sensor outputs comprise sensor outputs from one or more physical sensors.

8. The method of claim 7, wherein the plurality of sensor outputs comprise sensor outputs from one or more non-physical sensors.

9. The method of claim 8, wherein at least one for the one or more non-physical sensors is a social network and the sensor outputs comprise a listing of communications on the social network.

10. The method of claim 1, wherein the abstract description of the system-of-systems is further updated based one or more of current system behaviors, current system lower-level functions, and current system constraints.

11. The method of claim 1, further comprising:
performing an interpolation based on the currently available system resources to determine predicted system resources that will be available at a future time,
wherein the abstract description of the system-of-systems is further updated based on the predicted system resources.

12. A computer-implemented method for designing a system-of-systems for adapting to unplanned scenarios, the method comprising:
generating a plurality of input configurations corresponding to a system-of-systems;
performing a planning workflow for each input configuration, the planning workflow comprising:
generating a potential need related to the system-of-systems,
identifying a plurality of feasible solutions that could satisfy the potential need, wherein each feasible solution comprises instructions for using resources included in the system-of-systems;
generating a simulation network comprising a plurality of simulation models based on an abstract description of the system-of-systems;
reconfiguring, in an abstraction engine, the simulation network by replacing the simulation network with an alternative simulation network when an event causing permanent structure or behavior damage is detected during simulation;
using the alternative simulation network to determine a number of the plurality of feasible solutions satisfying a user-selected objective; and
identifying a most resilient input configuration corresponding to an input configuration having a greatest number of the plurality of feasible solutions in comparison to other input configurations included in the plurality of input configurations.

13. The method of claim 12, further comprising:
based on the most resilient input configuration, presenting a graphical user interface comprising: (i) a listing of selected system resources; (ii) a listing of selected system behaviors; and (iii) an indication of one or more relationships between the selected system resources and the selected system behaviors.

14. The method of claim 13, wherein the graphical user interface is presented via an Internet web browser on a user device.

15. The method of claim 12, wherein a parallel computing environment is used to execute the plurality of simulation models in parallel to determine the number of the plurality of feasible solutions satisfying the user-selected objective.

16. The method of claim 12, wherein the potential need related to the system-of-systems is generated by randomly modifying one or more values in the abstract description of the system-of-systems.

17. The method of claim 12, wherein the potential need related to a system-of-systems is generated based probabilities of failure or unavailability of system resources and links between the system resources.

18. The method of claim 12, wherein the plurality of feasible solutions that could satisfy the potential need are identified based on currently available resources associated with the system-of-systems.

19. A system for designing a system-of-systems for adaptation to unplanned scenarios, the system comprising:
a sensor interface configured to receive a plurality of sensor outputs related to a system-of-systems;
one or more processors configured to:
consolidate the plurality of sensor outputs into a current system status report,
in response to detection of a new unplanned need, identify currently available system resources,
update an abstract description of the system-of-systems based on the currently available system resources,
use the abstract description of the system-of-systems to determine a plurality of feasible solutions that could satisfy the new unplanned need, wherein each feasible solution comprises instructions for using resources included in the system-of-systems,
generate a simulation network comprising a plurality of simulation models based on the abstract description of the system-of-systems,
reconfigure, in an abstraction engine, the simulation network by replacing the simulation network with an alternative simulation network when an event causing permanent structure or behavior damage is detected during simulation; and
use the simulation network to select one of the plurality of feasible solutions; and
a presentation interface configured to use the selected feasible system configuration to presenting a graphical user interface comprising: (i) a listing of selected system resources; (ii) a listing of selected system behaviors; and (iii) an indication of one or more relationships between the selected system resources and the selected system behaviors.

20. The system of claim 19, wherein the one or more processors are included in a parallel processing platform configured to execute the plurality of simulation models in parallel to select the selected feasible solution.
